(19) United States
(12) Patent Application Publication
(10) Pub. No.: US 2026/0367140 A1
(43) Pub. Date: Nov. 19, 2026

(54) VOLTAGE MONITOR BUILT-IN SELF-TEST SYSTEM

(71) Applicant: STMicroelectronics International N.V., Geneva (CH)

(72) Inventors: Rajesh Narwal, Greater Noida (IN); Kushal N Trivedi, Noida (IN); Pravesh Kumar Saini, Greater Nodia (IN)

(21) Appl. No.: 19/211,791

(22) Filed: May 19, 2025

(51) Int. Cl. G01R 31/28; G01R 19/165; G01R 35/00

(52) U.S. Cl. CPC G01R 31/2856; G01R 19/16576; G01R 35/00

(57) ABSTRACT

According to an embodiment, a voltage monitor built-in self-test (BIST) system includes a regulator bandgap source providing a reference voltage to a regulator and an analog buffer, a monitor bandgap source providing a monitor reference voltage, and a comparator comparing a regulated voltage with the monitor reference voltage. The system includes switches and control signals that enable operation in functional and BIST modes. In functional mode, the system continuously monitors the regulated voltage against the monitor reference voltage. In BIST mode, the system verifies operation condition of bandgap sources, comparator, and switches by applying test voltages and observing comparator output transitions. The system leverages parasitic capacitance to detect switch faults through charging and discharging patterns.

### TECHNICAL FIELD

The present disclosure generally relates to design for testing (DFT) and, in particular embodiments, to a voltage monitor built-in self-test (BIST) system.

### BACKGROUND

Electronic systems, such as those used in automotive applications, use voltage monitors to detect whether particular supply domains operate within proper voltage ranges. These monitors contribute to the system’s safety and operation by triggering protective actions.

When voltages exceed or fall below acceptable thresholds, the monitors can trigger protective actions such as system resets or power shutdowns. This monitoring capability serves safety-critical applications where unexpected voltage fluctuations can lead to system failures with potentially serious consequences.

In safety-critical applications, such as automotive systems, the reliability of the monitoring system itself becomes an important consideration. The monitoring systems may need verification mechanisms to ensure they function correctly before the system enters normal operation. This helps maintain the overall safety and reliability of the electronic system.

### SUMMARY

Technical advantages are generally achieved by embodiments of this disclosure, which describe a voltage monitor built-in self-test (BIST) system.

A first aspect relates to a method for performing a built-in self-test (BIST) of a voltage monitor circuit, the method comprising configuring the voltage monitor circuit into a test mode, comprising decoupling a functional mode monitoring path by opening a first switch, establishing a test path by closing a second switch, and enabling an analog buffer to generate test voltages, applying a high threshold voltage to a non-inverting input of a comparator in the voltage monitor circuit; applying a low threshold voltage to the non-inverting input of the comparator; and monitoring an output of the comparator in response to the applied threshold voltages to verify operation of the comparator and bandgap sources in the voltage monitor circuit, wherein an inverting input of the comparator is coupled to a monitor reference voltage from a monitor bandgap source, and wherein the high threshold voltage and the low threshold voltage are derived from a separate regulator bandgap source to provide redundant monitoring.

A second aspect relates to a method for testing and operating a voltage monitor circuit in an electronic system, the method comprising performing a built-in self-test (BIST) of the voltage monitor circuit, comprising testing bandgap sources and a comparator of the voltage monitor circuit by applying test voltages to an input of the comparator and monitoring output transitions of the comparator, and testing switches in the voltage monitor circuit by manipulating the switches and monitoring resulting output changes of the comparator; and transitioning to a functional operating mode after performing the BIST and verifying a functional mode operation of the voltage monitor circuit, comprising establishing a monitoring path from a regulated voltage to the comparator, decoupling a test path from the comparator, and monitoring output of the comparator to detect voltage excursions outside acceptable limits, wherein the voltage monitor circuit includes separate regulator and monitor bandgap sources to provide redundant monitoring.

A third aspect relates to a voltage monitor circuit for providing continuous voltage monitoring with built-in self-test capability, the voltage monitor circuit comprising a regulator bandgap source configured to provide a reference voltage; a regulator coupled to the regulator bandgap source and configured to generate a regulated voltage; a monitor bandgap source configured to provide a monitor reference voltage independent from the reference voltage; a comparator having a non-inverting input and an inverting input, wherein the inverting input is coupled to the monitor reference voltage; a first switch coupled between the regulator and the non-inverting input of the comparator and configured to establish a functional mode monitoring path during normal operation; an analog buffer coupled to the regulator bandgap source and configured to generate a high threshold voltage and a low threshold voltage for testing; a multiplexer coupled to the analog buffer and configured to select between the high threshold voltage and the low threshold voltage based on a control signal; and a second switch coupled between the multiplexer and the non-inverting input of the comparator and configured to establish a test path during built-in self-test operations.

Embodiments can be implemented in hardware, software, or any combination thereof.

### BRIEF DESCRIPTION OF THE DRAWINGS

For a more complete understanding of the present disclosure and the advantages thereof, reference is now made to the following descriptions taken in conjunction with the accompanying drawings, in which:

FIG. 1 is a schematic of an example monitor circuit for testing voltage monitors of a system-on-chip (SoC);

FIG. 2 is a schematic of an embodiment monitor circuit for testing voltage monitors in a system-on-chip (SoC);

FIG. 3 is a flowchart of an embodiment method for operating a monitor circuit in a functional operating mode;

FIG. 4 is a flowchart of an embodiment method for operating a monitor circuit in a first analog BIST operating mode;

FIG. 5 is a flowchart of an embodiment method for operating a monitor circuit in a second analog BIST operating mode;

FIG. 6A is an embodiment timing diagram of the operation of a monitor circuit in a first BIST mode;

FIG. 6B is an embodiment timing diagram of the operation of a monitor circuit in a second BIST mode;

FIG. 7 is an embodiment timing diagram of the operation of multiple monitor circuits in the first BIST mode;

FIG. 8 is a schematic of an embodiment analog buffer;

FIG. 9 is a block diagram of an embodiment controller, which may be used to control the operation of a monitor circuit; and

FIG. 10 is a block diagram of an embodiment system-on-chip that includes multiple voltage monitors.

### DETAILED DESCRIPTION OF ILLUSTRATIVE EMBODIMENTS

This disclosure provides many applicable inventive concepts that can be embodied in a wide variety of specific contexts. The particular embodiments are merely illustrative of specific configurations and do not limit the scope of the claimed embodiments. Features from different embodiments may be combined to form further embodiments unless noted otherwise. Various embodiments are illustrated in the accompanying drawing figures, where identical components and elements are identified by the same reference number, and repetitive descriptions are omitted for brevity.

Variations or modifications described in one of the embodiments may also apply to others. Further, various changes, substitutions, and alterations can be made herein without departing from the spirit and scope of this disclosure as defined by the appended claims.

While the inventive aspects are described primarily in the context of automotive electronic systems, it should be appreciated that these inventive aspects may also apply to industrial control systems, medical devices, aerospace applications, and consumer electronics. In particular, aspects of this disclosure may similarly apply to safety-critical systems where voltage monitoring is used for monitoring operating conditions, data centers requiring high-reliability power management, battery-powered devices needing precise voltage regulation, and telecommunications infrastructure requiring an uninterrupted operation.

Embodiments of the disclosure provide a Built-In Self-Test (BIST) system for voltage monitors in electronic systems. The BIST system verifies the operational condition of voltage monitors immediately after power-up and before entering functional mode. The system can employ two independent bandgap reference circuits—one for the regulator and another for the monitor—to ensure safety through redundancy.

In embodiments, the monitor circuit includes a comparator with switches that allow it to operate in functional and test modes. The system can continuously monitor supply voltages against reference thresholds during functional mode. In test mode, the system can sequentially test each monitor while masking the outputs of other monitors to prevent false triggers.

The BIST scheme can, for example, identify faulty bandgap references, faulty monitor comparators, and faults in the sense path or BIST path switches. The testing process can verify operational conditions by checking for digital pulses when test conditions are applied at the comparator inputs. The system can leverage parasitic capacitance at the comparator input to detect switch faults through charging and discharging patterns.

Aspects of the disclosure provide high-resolution monitor threshold detection with trimmable voltage differences ranging from, for example, 10 to 70 millivolts. The comprehensive testing can include bandgap reference verification with minimal additional circuitry requirements. The serial testing approach maintains safety coverage while minimizing area and power overhead.

The voltage monitor BIST system can be particularly beneficial in applications where safety standards demand high reliability from monitoring systems. By verifying monitor functionality before normal operation begins, the system helps prevent potential damage or unsafe operation that might result from undetected voltage excursions. These and additional details are further discussed below.

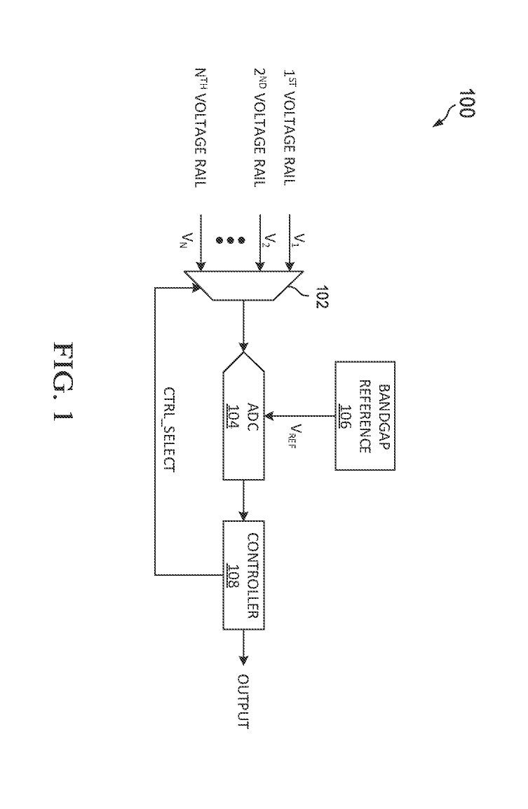

FIG. 1 illustrates a schematic of an example monitor circuit 100 for testing voltage monitors of a system-on-chip (SoC). Monitor circuit 100 includes a multiplexer 102, an analog-to-digital converter (ADC) 104, a bandgap reference source 106, and a controller 108.

Monitor circuit 100 represents a conventional implementation that can be implemented as a Built-In Self-Test (BIST) circuit for voltage monitors. Generally, multiple voltage monitors are employed within a system-on-chip (SoC). The voltage monitors grant a minimum voltage to support a certain clock frequency for the system-on-chip. For example, a subset of the voltage monitors of the system-on-chip monitor a lower voltage (LVD), and a subset of the voltage monitors of the system-on-chip monitor a higher voltage (HVD) or an ultra-high voltage (UVD), which can depend on the technology limitations employed within the system. If any monitor is triggered, the system-on-chip can be configured to, for example, reset or generate a destructive reset to cut off the supply.

To ensure the operation condition of each voltage monitor within the system-on-chip, a BIST is generally developed to check whether each voltage monitor works correctly before the system-on-chip begins to run code or start an operation. This ensures that the voltage monitors function correctly and detect voltages within their specified ranges. The BIST is run immediately after startup. If any of the voltage monitors trigger, its value can be stored in a register, which can be read to determine which monitor has caused the trigger, and the cause of the trigger during the BIST mode can be investigated.

It should be appreciated that the exact troubleshooting operation and trigger reaction can depend on the system-on-chip behavior. For example, in some cases, it can set a flag as an output inside a register, it can cause a hard reset, or perform other appropriate actions in response to the determining that the voltage monitor being checked during BIST mode is not working properly.

As shown, N voltage rails provide N voltages, including a first voltage rail providing a first voltage (V_{₁}), a second voltage rail providing a second voltage (V₂), and an N^{th} voltage rail providing an N^{th} voltage (V_{N}). N can be an integer greater than one. However, as illustrated in FIG. 1, N is greater than 2, indicating that the monitor circuit 100 can handle multiple voltage rails beyond just the first and second rails explicitly shown.

Each voltage rail is coupled to a respective input of multiplexer 102. The multiplexer 102 selects one of the voltage rails at a time based on a selection signal received from controller 108.

The output of multiplexer 102 is coupled to an input of ADC 104. The ADC 104 converts the analog voltage from the selected voltage rail into a digital representation. The ADC 104 receives a reference voltage (V_{REF}) from bandgap reference source 106, which provides a stable reference for the analog-to-digital conversion process. The digital output from ADC 104 is provided to controller 108, which processes the digital values to determine if the monitored voltages are within acceptable ranges.

In some arrangements, a sample-and-hold (S/H) circuit can be added between the output of multiplexer 102 and the input of ADC 104. Such a sample-and-hold circuit may include a sampling capacitor and switches to capture and hold the voltage value during conversion. This helps ensure that the converted voltage remains stable throughout the ADC conversion cycle.

Controller 108 can be programmed with threshold values for each voltage rail. When the digital value from ADC 104 indicates that a voltage rail is outside its acceptable range, controller 108 can generate an output signal to trigger protective actions such as system resets or power shutdowns.

During operation, controller 108 sequentially selects each voltage rail through multiplexer 102. For example, controller 108 may first select the first voltage (V_{₁}), wait for ADC 104 to complete the conversion, process the result, select the second voltage (V₂), and so on.

The monitor circuit 100 can be implemented in electronic systems, such as automotive applications, to detect whether supply voltages remain within acceptable limits. This circuit uses ADC 104 to perform a sequential conversion of voltages from multiple voltage rails. The sequential approach means that only one voltage rail can be monitored at any given time, creating a serial monitoring pattern where each rail is sampled in turn.

An ADC, such as the ADC 104, has some conversion time that affects monitoring coverage. For example, if the ADC operates at one megahertz, it can take one microsecond to sample one analog input. As another example, if the ADC is an 8-bit successive approximation register (SAR) ADC, it can take approximately 10 to 12 microseconds to sample one analog input.

In an example scenario where there are 40 to 50 voltage monitors in the system-on-chip, or there are 40 to 50 voltage rails, once a voltage monitor or voltage rail is tested and takes one microsecond to sample the input, it will have to wait for 40 to 50 microseconds before that same monitor or voltage rail can be sampled again. During these intervals between samplings, voltage excursions on unmonitored rails may go undetected, creating potential gaps in the monitoring coverage.

A fast ADC is typically required to minimize these monitoring gaps, which introduces drawbacks. Fast ADCs with high sampling rates are generally more expensive, increasing the overall system cost. They also consume more power than slower ADCs, contributing to greater overall power consumption in the system. This represents an inefficient use of resources, particularly in power-sensitive applications.

Further, monitor circuit 100 consumes power on the monitored voltage rails during sampling to ensure low impedance. This power consumption occurs because sampling typically requires charging capacitors in the sample-and-hold circuit or within the ADC, drawing current from the monitored voltage rail. This additional power drain on the monitored rails is inefficient and can be problematic in energy-constrained systems or applications where minimizing power consumption is critical. These inefficiencies in power consumption can negatively impact battery life in portable devices or increase thermal management challenges in compact electronic systems.

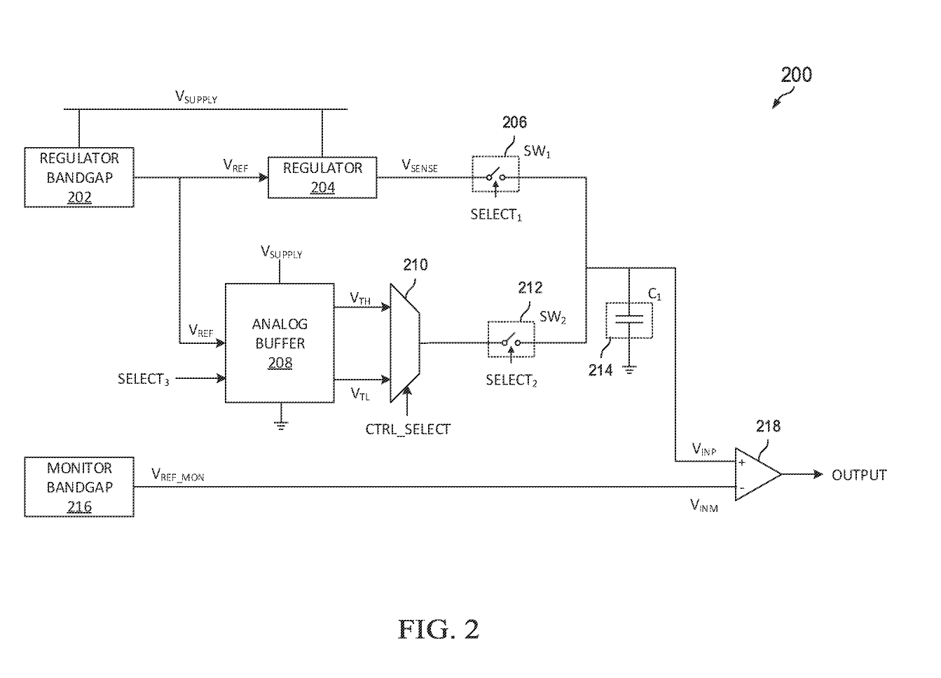

FIG. 2 illustrates a schematic of an embodiment monitor circuit 200 for testing voltage monitors in a system-on-chip (SoC). Monitor circuit 200 represents an improved embodiment of a Built-In Self-Test (BIST) circuit for verifying the operation condition of voltage monitors in the system-on-chip (SoC), addressing the limitations of conventional approaches such as monitor circuit 100 described in FIG. 1. Similar to the context discussed in FIG. 1, monitor circuit 200 can be used to ensure that voltage monitors function correctly before the system-on-chip begins operation, thereby guaranteeing that these monitors can properly detect voltage excursions during normal operation.

In embodiments, each monitor circuit 200 individually monitors a voltage monitor or voltage rail. In contrast to monitor circuit 100 of FIG. 1, which uses a single ADC to sequentially monitor multiple voltage rails, monitor circuit 200 provides dedicated monitoring for each voltage rail, eliminating the gaps in coverage inherent in sequential monitoring approaches.

Monitor circuit 200 includes a regulator bandgap source 202, a regulator 204, a first switch (SW₁) 206, an analog buffer 208, a multiplexer 210, a second switch (SW₂) 212, a parasitic capacitance (C₁) 214, a monitor bandgap source 216, and a comparator 218, which may be arranged as shown. Monitor circuit 200 may include additional components not shown, such as a controller to generate the various control signals for the multiplexer 210, the first switch (SW₁) 206, and the second switch (SW₂) 212. In embodiments, the various signals can be generated by one or more controllers of the system-on-chip.

Inside the system-on-chip, there are two bandgaps available. The regulator bandgap source 202 receives the supply voltage (V_{SUPPLY}) and provides a reference voltage (V_{REF}) to regulator 204 and the analog buffer 208. Regulator 204 also receives the supply voltage (V_{SUPPLY}). It generates a regulated voltage (V_{SENSE}) for the electronic system, which may correspond to a low voltage (LV) supply or a high voltage (HV) supply. The output of regulator 204 is coupled to the non-inverting input (V_{INP}) of the comparator 218 through the first switch (SW₁) 206, which can be opened or closed based on a first select (SELECT₁) signal.

The inverting input (V_{INM}) of the comparator 218 is coupled to the monitor bandgap source 216 of the system-on-chip, which provides a separate reference voltage (V_{REF_MON}). The general idea for having two bandgaps is for safety, which can be particularly advantageous in, for example, automotive applications. The regulator bandgap source 202 may correspond to the bandgap reference source 106 in FIG. 1; however, the additional monitor bandgap source 216 is added here to enhance safety.

Having a single bandgap (e.g., regulator bandgap source 202) providing the reference voltage to both the regulator 204 and the inverting input (V_{INM}) of the comparator 218 would result in the failure of coverage of common issues (e.g., noise) that affect both input paths to the comparator 218. Two separate bandgaps isolate the issues from the monitored path at the non-inverting input (V_{INP}) by providing a separate reference (V_{REF_MON}) through the monitor bandgap source 216. Accordingly, as using a common source for both paths would mask failures at the common bandgap source, the dual bandgap source architecture is implemented to provide enhanced safety.

The analog buffer 208 receives the supply voltage (V_{SUPPLY}), the reference voltage (V_{REF}) from the regulator bandgap source 202, and a third select (SELECT₃) signal. Analog buffer 208 generates two threshold voltages: a high threshold voltage (V_{TH}) and a low threshold voltage (V_{TL}). The high threshold voltage (V_{TH}) equals the reference voltage (V_{REF}) from the regulator bandgap source 202 plus a delta voltage (∆V). In contrast, the low threshold voltage (V_{TL}) equals the reference voltage (V_{REF}) from the regulator bandgap source 202 minus the delta voltage (∆V).

The third select (SELECT₃) signal enables or disables the analog buffer 208, controlling whether the high threshold voltage (V_{TH}) or the low threshold voltage (V_{TL}) signals are generated and available to pass through the multiplexer 210 and the second switch (SW₂) 212 to the comparator 218. When the third select (SELECT₃) signal is set to disable the analog buffer 208, the output of the multiplexer 210 is coupled to ground. This additional control signal provides more precise management of the BIST process by allowing the system to activate the analog buffer 208 only when needed for testing.

The multiplexer 210 selects between the high threshold voltage (V_{TH}) and the low threshold voltage (V_{TL}) based on a control (CTRL_SELECT) signal. The output of multiplexer 210 is coupled to the second switch (SW₂) 212, which can be opened or closed based on a second select (SELECT₂) signal. When closed, the second switch 212 allows the selected threshold voltage (i.e., the high threshold voltage (V_{TH}) or the low threshold voltage (V_{TL})) to be applied to the non-inverting input (V_{INP}) of comparator 218.

The comparator 218 compares the voltage at its non-inverting input (V_{INP}) with the monitor reference voltage (V_{REF_MON}) at its inverting input (V_{INM}). The output of comparator 218 indicates whether the sensed voltage is above or below the monitor reference voltage (V_{REF_MON}).

In embodiments, the output signal of the comparator 218 is digital. In such an embodiment, the output signal is at a logic level low in response to the voltages at the non-inverting input (V_{INP}) and the inverting input (V_{INM}) being equal and at a logic level high in response to voltages not being equal.

Monitor circuit 200 includes Built-In Self-Test (BIST) operating modes that verify the operation condition of various components before the system enters a functional operating mode. The BIST capability can identify potential failure points and verify the paths before normal operation begins.

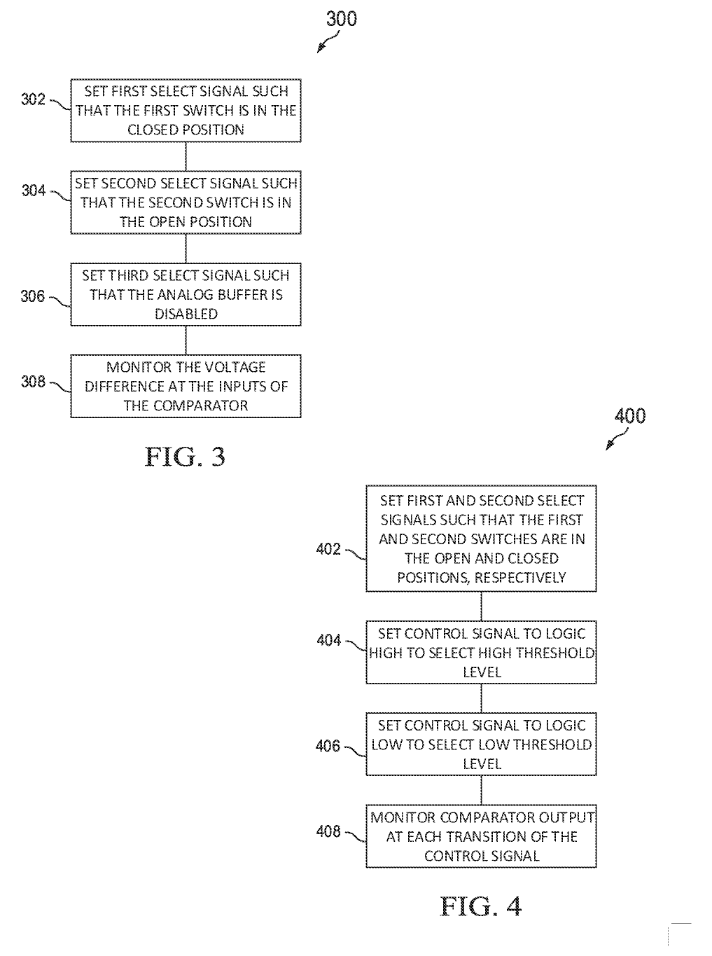

FIG. 3 illustrates a flowchart of an embodiment method 300 for operating monitor circuit 200 in a functional operating mode. The functional operating mode occurs after power-up and in response to the BIST sequences (i.e., completion of digital and analog BISTs), performing its operations without detecting a fault condition. In various embodiments, the method may include additional or fewer steps, or the steps may be performed differently than illustrated.

At step 302, the first select (SELECT₁) signal is set such that the first switch (SW₁) 206 is in a closed position. By closing the first switch (SW₁) 206, a continuous monitoring path is established where the regulated voltage (V_{SENSE}) from regulator 204 is directly coupled to the non-inverting input (V_{INP}) of comparator 218.

At step 304, the second select (SELECT₂) signal is set such that the second switch (SW₂) 212 is in an open position. By opening the second switch (SW₂) 212, the BIST path is decoupled from the non-inverting input (V_{INP}) of comparator 218.

At step 306, the third select (SELECT₃) signal is set such that the analog buffer 208 is disabled, preventing it from consuming power and generating the high threshold voltage (V_{TH}) or the low threshold voltage (V_{TL}) signals, as these signals are not needed during functional mode operation.

At step 308, comparator 218 compares the monitor reference voltage (V_{REF_MON}) from the monitor bandgap source 216 at its inverting input (V_{INM}) with the regulated voltage (V_{SENSE}) from regulator 204 at its non-inverting input (V_{INP}). The comparison determines whether the regulated voltage remains within acceptable limits defined by the monitor reference voltage (V_{REF_MON}).

In embodiments, a controller is coupled to the output of the comparator 218. In response to any unexpected value at the output of the comparator 218 indicating that the regulated voltage has exceeded acceptable limits, the controller can take protective actions such as signaling a fault condition for the voltage monitor or the voltage rail, setting a flag in a register, triggering a system reset, cutting off the supply voltage to protect sensitive components, or implementing other appropriate safety measures.

FIG. 4 illustrates a flowchart of an embodiment method 400 for operating monitor circuit 200 in a first analog BIST operating mode. In the first analog BIST operating mode, the monitor circuit 200 can identify faulty bandgap sources and comparators. In various embodiments, the method may include additional or fewer steps, or the steps may be performed differently than illustrated.

At step 402, the first select (SELECT₁) signal is set such that the first switch (SW₁) 206 is in an open position, and the second select (SELECT₂) signal is set such that the second switch (SW₂) 212 is in a closed position.

This configuration decouples the regulated voltage (V_{SENSE}) from the non-inverting input (V_{INP}) of comparator 218. It establishes a path for the test signals from the analog buffer 208 through the multiplexer 210 to reach the comparator 218. Additionally, the third select (SELECT₃) signal is set to enable the analog buffer 208 to generate the high threshold voltage (V_{TH}) and the low threshold voltage (V_{TL}) signals.

At step 404, the control (CTRL_SELECT) signal is set to a logic high level, causing the multiplexer 210 to select the high threshold voltage (V_{TH}) and apply it to the non-inverting input (V_{INP}) of comparator 218.

The high threshold voltage (V_{TH}) equals the reference voltage (V_{REF}) from the regulator bandgap source 202 plus a delta voltage (∆V). Since the high threshold voltage (V_{TH}) is greater than the monitor reference voltage (V_{REF_MON}) by the delta voltage (∆V), the output of comparator 218 is expected to be at a logic high level. If the output is not at the expected logic high level, this indicates a fault in either the regulator bandgap source 202, the monitor bandgap source 216, the analog buffer 208, or the comparator 218 itself.

At step 406, the control (CTRL_SELECT) signal is set to a logic low level, causing the multiplexer 210 to select the low threshold voltage (V_{TL}) and apply it to the non-inverting input (V_{INP}) of comparator 218.

The low threshold voltage (V_{TL}) equals the reference voltage (V_{REF}) from the regulator bandgap source 202 minus the delta voltage (∆V). Since the low threshold voltage (V_{TL}) is less than the monitor reference voltage (V_{REF_MON}) by the delta voltage (∆V), the output of comparator 218 is expected to be at a logic low level. If the output is not at the expected logic low level, this indicates a fault in the monitoring system.

At step 408, the output transitions of comparator 218 are evaluated to verify the operation condition of the bandgap sources and the comparator. By observing whether the comparator output properly transitions between logic high and logic low states in response to applying the high threshold voltage (V_{TH}) and the low threshold voltage (V_{TL}), the system can determine if all components function correctly.

If the output transitions occur as expected, this confirms that the regulator bandgap source 202 is generating an appropriate reference voltage (V_{REF}), the monitor bandgap source 216 is generating an appropriate monitor reference voltage (V_{REF_MON}), and the analog buffer 208 is correctly generating the threshold voltages. The comparator 218 can properly switch between output states. If any unexpected output behavior is detected, a controller coupled to the output of the comparator 218 can signal a fault condition, store the fault condition in a register, or take other appropriate actions before allowing the system to enter normal functional operation.

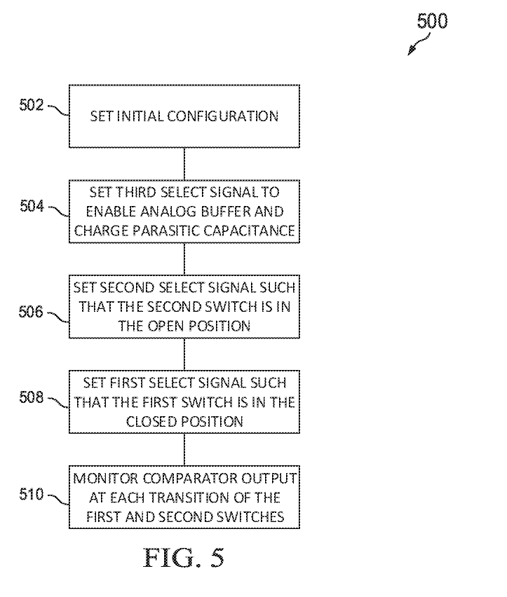

FIG. 5 illustrates a flowchart of an embodiment method 500 for operating monitor circuit 200 in a second analog BIST operating mode. In the second analog BIST operating mode, the monitor circuit 200 can identify a faulty first switch (SW₁) 206 in the sense path, a faulty second switch (SW₂) 212 in the BIST path, or both. In various embodiments, the method may include additional or fewer steps, or the steps may be performed differently than illustrated.

The monitor circuit 200 leverages the parasitic capacitance (C₁) 214 at the comparator input. The charging and discharging behavior of this capacitance, combined with the controlled enabling and disabling of the analog buffer 208 and the opening and closing of the switches, create distinctive voltage patterns at the non-inverting input (V_{INP}) that allow the system to verify proper switch operation without requiring additional test circuitry.

At step 502, the first select (SELECT₁) signal is set such that the first switch (SW₁) 206 is in an open position, the second select (SELECT₂) signal is set such that the second switch (SW₂) 212 is in a closed position, and the third select (SELECT₃) signal is set such that the analog buffer 208 is disabled.

This initial configuration prepares the monitor circuit 200 for testing the switches by establishing a known state where the non-inverting input (V_{INP}) of comparator 218 is coupled to ground through the closed second switch (SW₂) 212 and the disabled analog buffer 208. This connection actively discharges any charge stored in the parasitic capacitance (C₁) 214, ensuring the test begins from a known zero-voltage state.

Since the non-inverting input (V_{INP}) is discharged to ground potential and the inverting input (V_{INM}) is at the monitor reference voltage (V_{REF_MON}), which is positive, the output of comparator 218 is at a logic low level. This discharge step establishes a baseline for the test sequence’s subsequent charging and detection steps.

During this step, the voltage at the non-inverting input (V_{INP}) rises as the parasitic capacitance charges. If the second switch (SW₂) 212 functions correctly, the voltage at the non-inverting input (V_{INP}) will continue to rise. However, if the second switch (SW₂) 212 is faulty and not in the closed position, the parasitic capacitance will not charge, and the voltage at the non-inverting input (V_{INP}) will remain at ground potential.

During this step, the voltage at the non-inverting input (V_{INP}) rises as the parasitic capacitance charges. If the second switch (SW₂) 212 is functioning correctly, the parasitic capacitance (C₁) 214 will charge up to either the high threshold voltage (V_{TH}) or the low threshold voltage (V_{TL}) (depending on the CTRL_SELECT signal), and the output of the comparator 218 will change to reflect the difference between this voltage and monitor reference voltage (V_{REF_MON}) (approximately plus or minus the delta voltage).

However, if the second switch (SW₂) 212 is faulty and not in the closed position, the parasitic capacitance will not charge, and the voltage at the non-inverting input (V_{INP}) will remain at ground potential. In this case, the output of the comparator 218 will remain at a logic low level, indicating a fault in the second switch (SW₂) 212.

At step 506, the second select (SELECT₂) signal is set so that the second switch (SW2) 212 is open. This decouples the analog buffer 208 from the non-inverting input (V_{INP}) of comparator 218. If the second switch (SW₂) 212 is functioning correctly—as determined at step 504, the parasitic capacitance (C₁) 214 is isolated from the BIST path and will maintain its charge, keeping the voltage at the non-inverting input (V_{INP}) elevated.

However, if the second switch (SW₂) 212 is stuck in the closed position due to a defect—as determined in step 504, the non-inverting input (V_{INP}) will remain coupled to the analog buffer 208, preventing the proper testing of the first switch (SW₁) 206 in subsequent steps. Accordingly, if at step 504 it is determined that the second switch (SW₂) 212 is faulty, the test sequence can be configured to stop before transitioning to step 506.

At step 508, the first select (SELECT₁) signal is set such that the first switch (SW1) 206 is in a closed position. This couples the regulated voltage (V_{SENSE}) from regulator 204 to the non-inverting input (V_{INP}) of comparator 218. If the first switch (SW₁) 206 is functioning correctly, the voltage at the non-inverting input (V_{INP}) will change to match the regulated voltage (V_{SENSE}), causing the output of comparator 218 to change state if the regulated voltage differs from the previous voltage at the non-inverting input.

However, if the first switch (SW₁) 206 is stuck in the open position due to a defect, the voltage at the non-inverting input (V_{INP}) will not change, and the output of comparator 218 will remain in its previous state.

At step 510, the output of comparator 218 is observed during each step of the test sequence, and the system can determine whether the switches are functioning correctly. If the output of comparator 218 does not change as expected during the test sequence, a controller coupled to the output can identify which switch is faulty based on the specific pattern of output behavior.

Throughout the test sequence, the monitor bandgap source 216 continuously provides the monitor reference voltage (V_{REF_MON}) to the inverting input (V_{INM}) of comparator 218, providing a stable reference against which the changing voltages at the non-inverting input (V_{INP}) are compared.

This switch testing, combined with the bandgap and comparator testing performed in the first BIST operating mode, ensures that all critical components of the monitoring system are functioning correctly before the system enters normal operation.

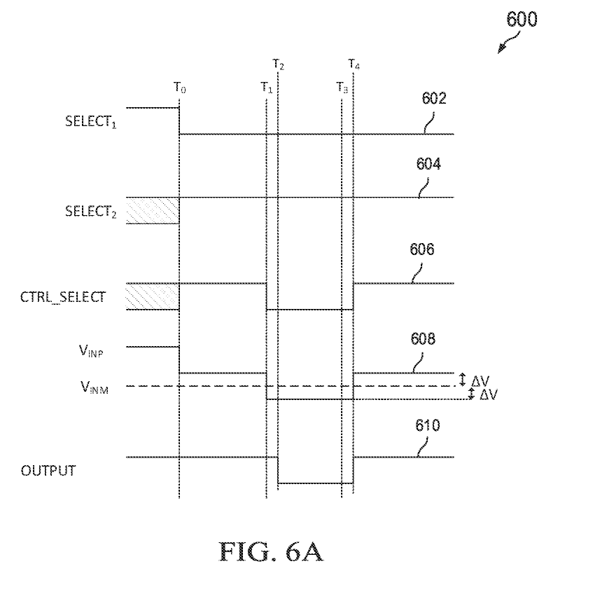

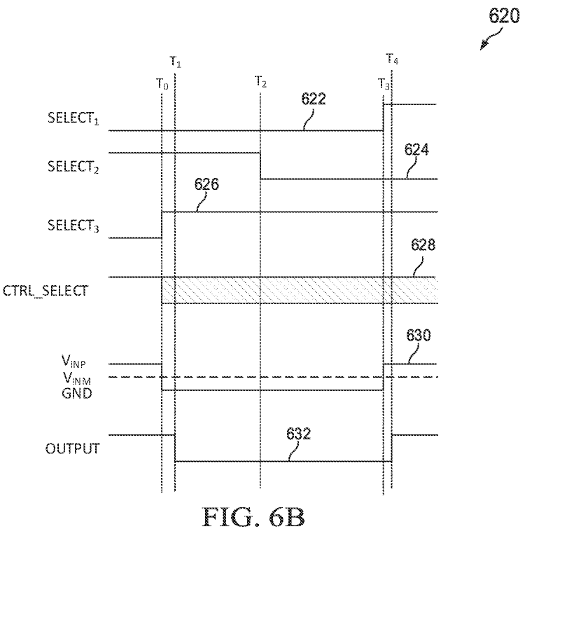

FIG. 6A illustrates an embodiment timing diagram 600 of the operation of the monitor circuit 200 in a first BIST operating mode. During the first BIST mode, the BIST can identify faulty bandgap sources and comparators.

At time T₀, the first select (SELECT₁) signal 602 transitions from logic high to logic low. As a result, the first switch (SW₁) 206 transitions from a closed position, as in the functional mode operation, to an open position. Simultaneously, the second select (SELECT₂) signal 604 transitions to a logic high level. As a result, the second switch (SW₂) 212 transitions from an open position, as in the functional mode operation, to a closed position.

At time T₀, the control (CTRL_SELECT) signal 606 transitions to a logic high level and remains at this level until time T₁. Depending on the configuration of the multiplexer 210, between times T₀ and T₁, the input to the non-inverting input (V_{INP}) of the comparator 218 is either the high threshold voltage (V_{TH}) or the low threshold voltage (V_{TL}).

Here, a logic high level at the control (CTRL_SELECT) signal 606 results in the output of the multiplexer 210 being equal to the high threshold voltage (V_{TH}), and a logic low level at the control (CTRL_SELECT) signal 606 results in the output of the multiplexer 210 being equal to the low threshold voltage (V_{TL}). It should be appreciated that in some embodiments, a reversal of the operation shown may be implemented.

At time T₁, the control (CTRL_SELECT) signal 606 transitions to a logic low level and remains at this level until time T₃. In response to the transition, at time T₁, the input to the non-inverting input (V_{INP}) of the comparator 218 is the low threshold voltage (V_{TL})—the reverse of the condition from times T₀ to T₁.

At time T₃, the control (CTRL_SELECT) signal 606 transitions back to a logic high level, where the input to the non-inverting input (V_{INP}) of the comparator 218 is the high threshold voltage (V_{TH})—similar to the input between times T₀ to T₁.

The monitor bandgap source 216 continuously provides the monitor reference voltage (V_{REF_MON}) to the inverting input (V_{INM}) of the comparator 218. Signal 608 illustrates the voltage differential between the non-inverting input (V_{INP}) and the inverting input (V_{INM}) during the first phase of BIST mode. The differential shows how the non-inverting input (V_{INP}) alternates between being above and below the inverting input (V_{INM}) by the delta voltage (∆V), creating a controlled test condition for comparator 218.

Before time T₂ and after time T₄, since V_{TH} > V_{REF_MON}, the output signal 610 of comparator 218 is at a logic high level. Between times T₂ and T₄, since V_{TL} < V_{REF_MON}, the output signal 610 of comparator 218 is at a logic low level.

As shown, there is a time delay between the transitions of the control (CTRL_SELECT) signal 606 at times T₁ and T₃ and the transition of the output signal 610 at times T₂ and T4, respectively. The delay represents the response time of comparator 218 to changes in the input voltage differential shown in signal 608.

During the first phase of BIST mode, the non-inverting input (V_{INP}) of comparator 218 is provided with voltages that are offset from the monitor reference voltage (V_{REF_MON}) by the delta voltage (∆V). Specifically, the high threshold voltage (V_{TH}) equals the sum of the reference voltage (V_{REF}) and the delta voltage (∆V), while the low threshold voltage (V_{TL}) equals the difference between the reference voltage (V_{REF}) and the delta voltage (∆V). This creates the controlled voltage differential at the comparator inputs shown in signal 608 that can be used to verify proper operation.

By sequentially applying the high threshold voltage (V_{TH}) and the low threshold voltage (V_{TL}) to the non-inverting input (V_{INP}) of comparator 218 and observing the transitions in the output signal 610, the system can verify whether the bandgap references are providing appropriate voltage levels and whether the comparator can properly switch between output states.

For example, when the high threshold voltage (V_{TH}) is provided to the non-inverting input (V_{INP}) of comparator 218, as the high threshold voltage (V_{TH}) is greater than the monitor reference voltage (V_{REF_MON}) by the delta voltage (∆V), the output signal 610 before time T₂ and after time T₄ is expected to be at a logic high level. Likewise, when the low threshold voltage (V_{TL}) is provided to the non-inverting input (V_{INP}) of comparator 218, as the low threshold voltage (V_{TL}) is less than the monitor reference voltage (V_{REF_MON}) by the delta voltage (∆V), the output signal 610 between times T₂ and T₄ is expected to be at a logic low level.

Accordingly, if the output signal 610 is outside these expected values, a controller, for example, coupled to the output of the comparator 218, can detect an error during the BIST mode and signal a fault condition, store the fault condition in a register, or take other appropriate actions.

In an embodiment, the reference voltage (V_{REF}) and the monitor reference voltage (V_{REF_MON}) equal approximately 712 millivolts. In embodiments, the delta voltage (∆V) ranges from 10 to 70 millivolts. In embodiments, the delta voltage (∆V) is trimmable and can be adjusted for different requirements. In embodiments, the difference between times T₂ and T₄ is approximately twenty microseconds.

FIG. 6B illustrates an embodiment timing diagram 620 of the operation of a monitor circuit in a second analog BIST operating mode. During the second analog BIST mode, the monitor circuit 200 can identify a faulty first switch (SW₁) 206 in the sense path, a faulty second switch (SW₂) 212 in the BIST path, or both.

At time T₀, the initial configuration is established with the first select (SELECT₁) signal 622 at a logic low level, keeping the first switch (SW₁) 206 in an open position. The second select (SELECT₂) signal 624 is at a logic high level, placing the second switch (SW₂) 212 in a closed position. The third select (SELECT₃) signal 626 transitions to a logic high level, enabling the analog buffer 208.

This configuration couples the non-inverting input (V_{INP}) of comparator 218 to ground through the closed second switch (SW₂) 212 and the analog buffer 208, as shown in signal 630. Since the non-inverting input (V_{INP}) is at ground potential and the inverting input (V_{INM}) is at the monitor reference voltage (V_{REF_MON}), which is positive, the output signal 632 is at a logic low level.

Between times T₀ and T₃, the parasitic capacitance at the non-inverting input (V_{INP}) begins charging. If the second switch (SW₂) 212 is functioning correctly, the voltage at the non-inverting input (V_{INP}) will rise. If the second switch (SW₂) 212 were faulty and not in the closed position, the parasitic capacitance would not charge properly.

At time T₂, the second select (SELECT₂) signal 624 transitions to a logic low level, opening the second switch (SW₂) 212. This decouples the analog buffer 208 from the non-inverting input (V_{INP}) of comparator 218. If the second switch (SW₂) 212 is functioning correctly, the parasitic capacitance is isolated from the BIST path and maintains its charge, keeping the voltage at the non-inverting input (V_{INP}) elevated.

At time T₃, the first select (SELECT₁) signal 622 transitions to a logic high level, closing the first switch (SW₁) 206. This couples the regulated voltage (V_{SENSE}) from regulator 204 to the non-inverting input (V_{INP}) of comparator 218. If the first switch (SW₁) 206 is functioning correctly, the voltage at the non-inverting input (V_{INP}) changes to match the regulated voltage (V_{SENSE}), causing the output signal 632 to transition to a logic high level at time T₄.

Throughout the test sequence, the control (CTRL_SELECT) signal 628 remains at a constant level, and the monitor bandgap source 216 continuously provides the monitor reference voltage (V_{REF_MON}) to the inverting input (V_{INM}) of comparator 218.

By observing the output signal 632 during each step of the test sequence, the system can determine whether the switches are functioning correctly. If the output signal 632 does not change as expected during the test sequence, a controller coupled to the output can identify which switch is faulty based on the specific pattern of output behavior.

This switch testing leverages the parasitic capacitance at the comparator input to verify proper operation without requiring additional test circuitry. Combined with the bandgap and comparator testing performed in the first BIST operating mode, this ensures the critical components of the monitoring system function correctly before the system enters normal operation.

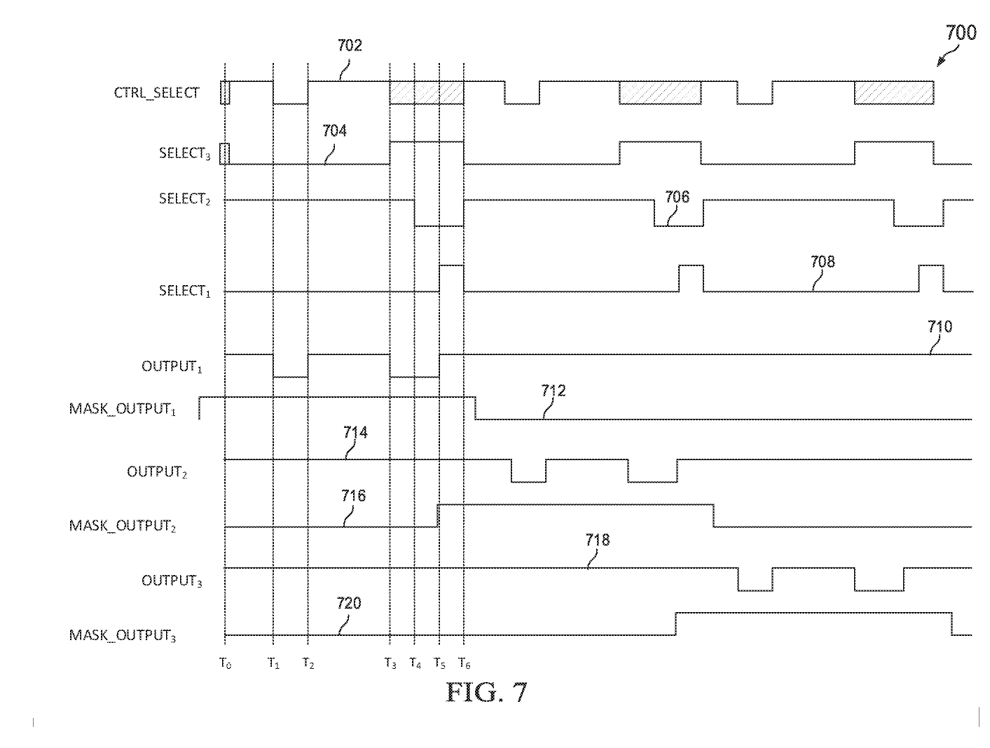

FIG. 7 illustrates an embodiment timing diagram 700 of the operation of multiple monitor circuits in the first and second BIST modes. It shows how the system sequentially tests multiple voltage monitors while masking their outputs to prevent false triggers. Timing diagram 700 includes a control (CTRL_SELECT) signal 702, a third select (SELECT₃) signal 704, output signals 710, 714, 718 from three different monitor circuits, and their corresponding mask output signals 712, 716, 720.

The timing diagram 700 illustrates how the first BIST operating mode described in method 400 and the second BIST operating mode described in method 500 can be applied sequentially across multiple monitor circuits in a system-on-chip implementation. This approach ensures that all voltage monitors are functioning correctly before the system enters normal operation, providing a robust safety mechanism with minimal additional circuitry requirements.

Timing diagram 700 demonstrates the serial testing approach used to verify multiple monitor circuits in a system-on-chip implementation. The testing process is divided into three time periods for testing a first monitor circuit, a second monitor circuit, and a third monitor circuit. Each time period is divided into two main phases: the first BIST mode from time T_{₀} to T₃ and the second BIST mode from time T₃ to T₆. The process is repeated for each monitor circuit. This sequential approach allows the system to thoroughly test each monitor circuit individually while preventing interference with the system’s digital logic.

During the first BIST mode from time T₀ and T₃, the system tests the bandgap sources and comparator of the first monitor circuit. The control (CTRL_SELECT) signal 702 toggles between high and low states, causing the multiplexer 210 in the first monitor circuit to alternate between selecting the high threshold voltage (V_{TH}) and the low threshold voltage (V_{TL}). The third select (SELECT₃) signal 704 is high during this period to enable the analog buffer in the first monitor circuit.

As a result, the output signal (OUTPUT₁) 710 of the first monitor circuit transitions between high and low states in response to the changing input at its comparator, demonstrating operation condition of the first monitor’s bandgap sources and comparator. During this testing period, the mask output signal (MASK_OUTPUT₁) 712 is set high, indicating that the output of the first monitor circuit is being masked or latched to prevent any transitions from triggering false alarms or resets in the system-on-chip’s digital logic.

During the second BIST mode from time T₃ and T₆, the system tests the switches in the first monitor circuit. The second select (SELECT₂) signal 706 and first select (SELECT₁) signal 708 are manipulated to test the operation of the switches. The output signal (OUTPUT₁) 710 continues to show transitions in response to these switch manipulations, while the mask output signal (MASK_OUTPUT₁) 712 remains high to continue masking these transitions from affecting the system.

The output signals (OUTPUT₂) 714 and (OUTPUT₃) 718 from the second and third monitor circuits, along with their corresponding mask output signals (MASK_OUTPUT₂) 716 and (MASK_OUTPUT₃) 720, are also shown in the timing diagram. These signals represent the outputs of monitor circuits that are not currently being tested but will be tested in subsequent testing sequences.

After time T₆, the same testing process would be repeated for the second monitor circuit, followed by the third monitor circuit, and so forth. During each circuit’s testing period, its corresponding mask output signal would be set high while the others would be low, ensuring that only the outputs from circuits not under test affect the system’s operation.

This sequential testing approach allows the system to verify the operation condition of each monitor circuit’s bandgap sources and comparator without disrupting the system’s overall voltage monitoring function. By masking the output of each monitor circuit during its test period, the system prevents false triggers that might otherwise occur due to the deliberate voltage transitions applied during testing. Once each monitor circuit has been verified, the next monitor circuit undergoes testing.

The masking mechanism shown in the timing diagram can be implemented by latching the output of each monitor during its test period. This latched value is used by the system’s digital logic instead of the actual monitor output, ensuring that the deliberate transitions caused by the test do not impact the system’s operation. Once testing of a particular monitor is complete, its mask is removed.

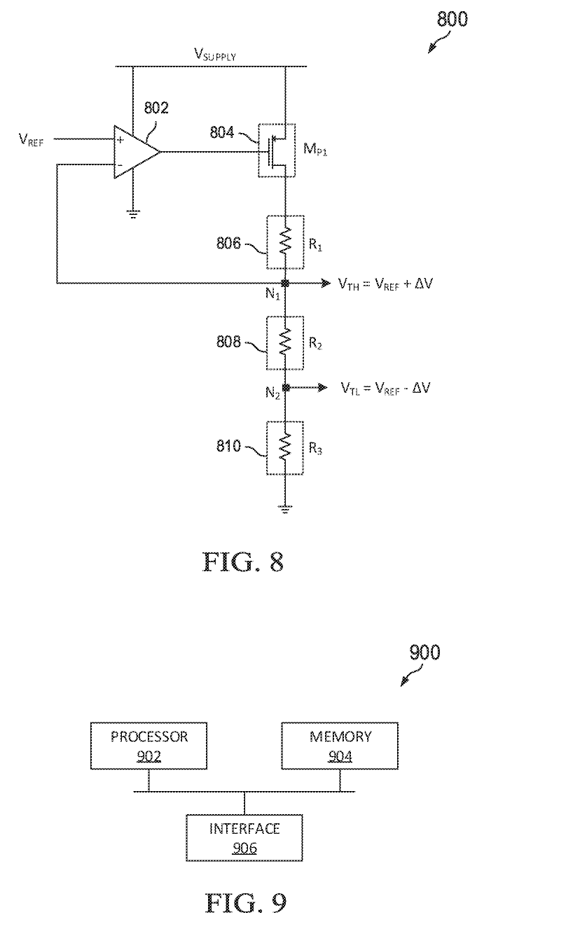

FIG. 8 illustrates a schematic of an embodiment analog buffer 800, which may be implemented as the analog buffer 208 of FIG. 2. Analog buffer 800 includes a buffer amplifier 802, a p-channel transistor (M_{P1}) 804, a first resistor (R₁) 806, a second resistor (R₂) 808, and a third resistor (R₃) 810), which may (or may not) be arranged as shown. Analog buffer 800 may include additional components not shown, such as capacitors.

The non-inverting input of the buffer amplifier 802 is coupled to the regulator bandgap source 202, which receives the reference voltage (V_{REF}). The inverting input of the buffer amplifier 802 is coupled to a first node (N₁) shared between the first resistor (R₁) 806 and the second resistor (R₂) 808), which provides a negative feedback path. The output of the buffer amplifier 802 is coupled to the gate terminal of the p-channel transistor (M_{P1}) 804.

The source terminal of the p-channel transistor (M_{P1}) 804 is coupled to the supply voltage (V_{SUPPLY}). The drain terminal of the p-channel transistor (M_{P1}) 804 is coupled to a first terminal of the first resistor (R₁) 806. The second terminal of the first resistor (R₁) 806 is coupled to the first node (N₁) and to a first terminal of the second resistor (R₂) 808. The second terminal of the second resistor (R₂) 808 is coupled to a second node (N₂) and to a first terminal of the third resistor (R₃) 810. The second terminal of the third resistor (R₃) 810 is coupled to ground.

The analog buffer 800 functions as a voltage divider with feedback to generate two threshold voltages from the reference voltage (V_{REF}). The buffer amplifier 802 and p-channel transistor (M_{P1}) 804 form a feedback loop that maintains the voltage at the first node (N₁) equal to the reference voltage (V_{REF}). Due to the voltage drop across the first resistor (R₁) 806, the voltage at the first node (N₁) is higher than the reference voltage by a delta voltage (∆V), resulting in V_{REF} + ∆V. This voltage serves as the high threshold voltage (V_{TH}) output of the analog buffer.

Similarly, due to the voltage drop across the second resistor (R₂) 808, the voltage at the second node (N₂) is lower than the reference voltage by the delta voltage (∆V), resulting in V_{REF} - ∆V. This voltage serves as the low threshold voltage (V_{TL}) output of the analog buffer.

The values of the first resistor (R₁) 806, the second resistor (R₂) 808, and the third resistor (R₃) 810 can be selected to set the desired delta voltage (∆V). In embodiments, these resistors may be trimmable to allow adjustment of the delta voltage (∆V), providing flexibility for different monitoring requirements.

When the third select (SELECT₃) signal (not shown in FIG. 8) disables the analog buffer 800, the p-channel transistor (M_{P1}) 804 can be turned off, preventing current flow through the resistor network and thus disabling the generation of the high threshold voltage (V_{TH}) and the low threshold voltage (V_{TL}). This capability allows the analog buffer 800 to be powered down when not needed, such as during functional mode operation, reducing power consumption.

FIG. 9 illustrates a block diagram of an embodiment controller 900, which may be used to control the operation of the monitor circuit 200. Controller 900 includes a processor 902, a memory 904, and an interface 906, which may (or may not) be arranged as shown. Controller 900 may include additional components not shown.

The controller 900 can be implemented on the same system-on-chip as the monitor circuit 200 or may be external to the system-on-chip. The processor 902 executes instructions stored in the memory 904 to control the operation of the monitor circuit 200 and to process information received from the monitor circuit 200. Interface 906 provides communication between controller 900 and the various components of monitor circuit 200, including voltage monitors and other components.

During operation, processor 902 generates control signals transmitted through interface 906 to operate the monitor circuit 200 based on the previously described operating modes. These control signals include but are not limited to, the first select (SELECT₁) signal for controlling the first switch (SW₁) 206, the second select (SELECT₂) signal for controlling the second switch (SW₂) 212, the third select (SELECT₃) signal for enabling or disabling the analog buffer 208, and the control (CTRL_SELECT) signal for controlling the multiplexer 210.

Controller 900 can be configured to monitor the output of comparator 218 through interface 906. Based on the output of the comparator 218 during the various BIST operating modes, processor 902 can determine whether the components of the monitor circuit 200 are functioning correctly. If a fault is detected, the processor 902 can signal a fault condition through interface 906.

Memory 904 can be a non-transitory memory that stores instructions that, when executed by processor 902, cause the processor to perform the various operations described herein. These instructions can include instructions for controlling the BIST operating modes, managing the transition between different operating modes, processing the output of the comparator 218, and determining appropriate responses to detected fault conditions.

The memory 904 can include registers to store fault conditions detected during the BIST operating modes. These registers can store information about which components of the monitor circuit 200 have failed, such as a faulty bandgap source, a faulty comparator, or a faulty switch. Although the monitor circuit 200 may include dedicated registers for storing this information, centralizing fault information in the controller 900 can allow for more comprehensive system-level fault management.

In addition to controlling the BIST operating modes, the controller 900 can also manage the transition from BIST mode to functional mode after verifying that all components function correctly. During functional mode, controller 900 continues to monitor the output of comparator 218 to detect any voltage excursions outside acceptable limits. If such excursions are detected, the controller 900 can initiate appropriate protective actions, such as system resets or power shutdowns.

Controller 900 can also be configured to perform periodic BIST operations during system operation to ensure the continued reliability of the voltage monitoring system. These periodic tests can be scheduled during times of low system activity to minimize impact on normal operation.

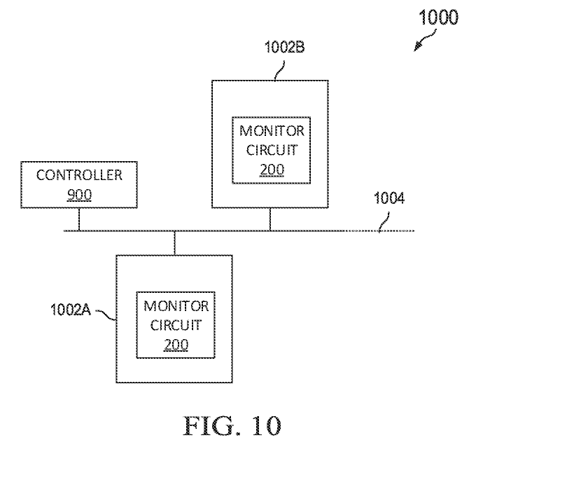

FIG. 10 illustrates a block diagram of an embodiment system-on-chip 1000 that includes multiple voltage monitors implemented in a system-on-chip. System-on-chip 1000 includes a controller 900 and voltage monitors 1002A-B, which may be arranged as shown. Although only two voltage monitors are explicitly illustrated, the number of voltage monitors is non-limiting, and system-on-chip 1000 may include additional voltage monitors beyond those shown. Other arrangements of the components are also contemplated.

In embodiments, each voltage monitor 1002 includes a monitor circuit 200, as described in connection with FIG. 2. These monitor circuits 200 provide dedicated monitoring for different voltage rails within the system-on-chip, eliminating the gaps in coverage inherent in sequential monitoring approaches. By implementing multiple instances of monitor circuit 200, system-on-chip 1000 can monitor multiple voltage rails, providing protection against voltage excursions.

The controller 900, as described in connection with FIG. 9, is coupled to each of the voltage monitors 1002A-B through a communication bus 1004. The controller 900 provides the control signals necessary to operate each monitor circuit 200, including the first select (SELECT₁) signal, the second select (SELECT₂) signal, the third select (SELECT₃) signal, and the control (CTRL_SELECT) signal. These signals can be individually addressed to each voltage monitor, allowing the controller 900 to independently control the operation of each monitor circuit 200.

During system initialization, controller 900 can sequentially perform BIST operations on each voltage monitor to verify operation condition before entering functional mode. This sequential testing approach allows the system to identify faulty components within each voltage monitor. Once all voltage monitors have been verified, the system can transition to functional mode, where each monitor circuit 200 continuously monitors its assigned voltage rail.

In functional mode, each voltage monitor 1002 operates independently to monitor its assigned voltage rail. If any voltage monitor detects a voltage excursion outside acceptable limits, it can signal this condition to controller 900. The controller 900 can then take appropriate protective actions based on which voltage rail has experienced the excursion and the severity of the excursion.

The system-on-chip 1000 provides several advantages over conventional voltage monitoring approaches. The system eliminates the monitoring gaps inherent in sequential ADC-based approaches by using dedicated monitor circuits for each voltage rail. The BIST capability ensures that all monitoring components function correctly before transitioning to the functional mode. The dual bandgap architecture in each monitor circuit provides enhanced safety through redundancy, which can be advantageous in automotive applications. Additionally, the system can be implemented with minimal additional circuitry compared to conventional approaches, making it an efficient solution for comprehensive voltage monitoring in system-on-chip designs.

A first aspect relates to a method for performing a built-in self-test (BIST) of a voltage monitor circuit, the method comprising configuring the voltage monitor circuit into a test mode, comprising decoupling a functional mode monitoring path by opening a first switch, establishing a test path by closing a second switch, and enabling an analog buffer to generate test voltages, applying a high threshold voltage to a non-inverting input of a comparator in the voltage monitor circuit; applying a low threshold voltage to the non-inverting input of the comparator; and monitoring an output of the comparator in response to the applied threshold voltages to verify operation of the comparator and bandgap sources in the voltage monitor circuit, wherein an inverting input of the comparator is coupled to a monitor reference voltage from a monitor bandgap source, and wherein the high threshold voltage and the low threshold voltage are derived from a separate regulator bandgap source to provide redundant monitoring.

In a first implementation form of the method, according to the first aspect as such, the method further comprising, after verifying operation condition of the comparator and bandgap sources configuring the voltage monitor circuit into a functional operating mode, comprising establishing the functional mode monitoring path by closing the first switch, decoupling the test path by opening the second switch, and disabling the analog buffer; and monitoring a voltage difference at the inputs of the comparator during the functional operating mode.

In a second implementation form of the method, according to the first aspect as such or any preceding implementation form of the first aspect, the method further comprising, after monitoring the output of the comparator testing operation of the first switch and the second switch, comprising disabling the analog buffer, charging a parasitic capacitance at the non-inverting input of the comparator, opening the second switch to decouple the test path, and closing the first switch to establish the functional mode monitoring path; and monitoring the output of the comparator during switching transitions to verify operation condition of the first switch and the second switch.

In a third implementation form of the method, according to the first aspect as such or any preceding implementation form of the first aspect, the high threshold voltage equals a reference voltage from the regulator bandgap source plus a delta voltage, and the low threshold voltage equals the reference voltage minus the delta voltage.

In a fourth implementation form of the method, according to the first aspect as such or any preceding implementation form of the first aspect, the delta voltage is trimmable.

In a fifth implementation form of the method, according to the first aspect as such or any preceding implementation form of the first aspect, the voltage monitor circuit is one of a plurality of voltage monitor circuits in a system-on-chip, and wherein the method further comprises sequentially testing each voltage monitor circuit.

In a sixth implementation form of the method, according to the first aspect as such or any preceding implementation form of the first aspect, the method further comprising storing fault conditions detected during the BIST in registers; and initiating protective actions in response to detecting voltage excursions outside acceptable limits.

A second aspect relates to a method for testing and operating a voltage monitor circuit in an electronic system, the method comprising performing a built-in self-test (BIST) of the voltage monitor circuit, comprising testing bandgap sources and a comparator of the voltage monitor circuit by applying test voltages to an input of the comparator and monitoring output transitions of the comparator, and testing switches in the voltage monitor circuit by manipulating the switches and monitoring resulting output changes of the comparator; and transitioning to a functional operating mode after performing the BIST and verifying a functional mode operation of the voltage monitor circuit, comprising establishing a monitoring path from a regulated voltage to the comparator, decoupling a test path from the comparator, and monitoring output of the comparator to detect voltage excursions outside acceptable limits, wherein the voltage monitor circuit includes separate regulator and monitor bandgap sources to provide redundant monitoring.

In a first implementation form of the method, according to the second aspect as such, testing the bandgap sources and the comparator comprises configuring the voltage monitor circuit into a test mode by decoupling the monitoring path, establishing the test path, and enabling an analog buffer; applying a high threshold voltage to a non-inverting input of the comparator; applying a low threshold voltage to the non-inverting input of the comparator; and monitoring the output of the comparator in response to the applied threshold voltages.

In a second implementation form of the method, according to the second aspect as such or any preceding implementation form of the second aspect, testing the switches comprises configuring the voltage monitor circuit into a switch test mode; charging a parasitic capacitance at a non-inverting input of the comparator; manipulating states of the switches to transition between the test path and the monitoring path; and monitoring the output of the comparator during the transitions to verify operation of the switches.

In a third implementation form of the method, according to the second aspect as such or any preceding implementation form of the second aspect, establishing the monitoring path comprises closing a first switch that couples the regulated voltage to a non-inverting input of the comparator.

In a fourth implementation form of the method, according to the second aspect as such or any preceding implementation form of the second aspect, decoupling the test path comprises opening a second switch that couples an analog buffer to a non-inverting input of the comparator.

In a fifth implementation form of the method, according to the second aspect as such or any preceding implementation form of the second aspect, the voltage monitor circuit is one of a plurality of voltage monitor circuits in a system-on-chip, and wherein the method further comprises sequentially testing each voltage monitor circuit.

In a sixth implementation form of the method, according to the second aspect as such or any preceding implementation form of the second aspect, further comprising, in response to detecting voltage excursions outside acceptable limits, triggering protective actions including signaling a fault condition, storing the fault condition in a register, triggering a system reset, cutting off a supply voltage, or a combination thereof.

A third aspect relates to a voltage monitor circuit for providing continuous voltage monitoring with built-in self-test capability, the voltage monitor circuit comprising a regulator bandgap source configured to provide a reference voltage; a regulator coupled to the regulator bandgap source and configured to generate a regulated voltage; a monitor bandgap source configured to provide a monitor reference voltage independent from the reference voltage; a comparator having a non-inverting input and an inverting input, wherein the inverting input is coupled to the monitor reference voltage; a first switch coupled between the regulator and the non-inverting input of the comparator and configured to establish a functional mode monitoring path during normal operation; an analog buffer coupled to the regulator bandgap source and configured to generate a high threshold voltage and a low threshold voltage for testing; a multiplexer coupled to the analog buffer and configured to select between the high threshold voltage and the low threshold voltage based on a control signal; and a second switch coupled between the multiplexer and the non-inverting input of the comparator and configured to establish a test path during built-in self-test operations.

In a first implementation form of the voltage monitor circuit, according to the third aspect as such, the first switch is configured to be in a closed position and the second switch is configured to be in an open position during a functional operating mode of the voltage monitor circuit.

In a second implementation form of the voltage monitor circuit, according to the third aspect as such or any preceding implementation form of the third aspect, the first switch is configured to be in an open position and the second switch is configured to be in a closed position during a built-in self-test (BIST) operating mode of the voltage monitor circuit.

In a third implementation form of the voltage monitor circuit, according to the third aspect as such or any preceding implementation form of the third aspect, wherein the high threshold voltage equals the reference voltage plus a delta voltage, and wherein the low threshold voltage equals the reference voltage minus the delta voltage.

In a fourth implementation form of the voltage monitor circuit, according to the third aspect as such or any preceding implementation form of the third aspect, the voltage monitor circuit comprising a parasitic capacitance at the non-inverting input of the comparator, wherein the parasitic capacitance is configured to charge and discharge during a switch testing mode to verify operation condition of the first switch and the second switch.

In a fifth implementation form of the voltage monitor circuit, according to the third aspect as such or any preceding implementation form of the third aspect, the analog buffer comprises a buffer amplifier having a non-inverting input coupled to the reference voltage; a p-channel transistor having a gate terminal coupled to an output of the buffer amplifier, a source terminal coupled to a supply voltage, and a drain terminal; a first resistor having a first terminal coupled to the drain terminal of the p-channel transistor and a second terminal coupled to a first node; a second resistor having a first terminal coupled to the first node and a second terminal coupled to a second node; and a third resistor having a first terminal coupled to the second node and a second terminal coupled to ground, wherein the first node provides the high threshold voltage and the second node provides the low threshold voltage.

Although the description has been described in detail, it should be understood that various changes, substitutions, and alterations may be made without departing from the spirit and scope of this disclosure as defined by the appended claims. The same elements are designated with the same reference numbers in the various figures. Moreover, the scope of the disclosure is not intended to be limited to the particular embodiments described herein, as one of ordinary skill in the art will readily appreciate from this disclosure that processes, machines, manufacture, compositions of matter, means, methods, or steps, presently existing or later to be developed, may perform substantially the same function or achieve substantially the same result as the corresponding embodiments described herein. Accordingly, the appended claims are intended to include within their scope such processes, machines, manufacture, compositions of matter, means, methods, or steps.

The specification and drawings are, accordingly, to be regarded simply as an illustration of the disclosure as defined by the appended claims, and are contemplated to cover any and all modifications, variations, combinations, or equivalents that fall within the scope of the present disclosure.

What is claimed is:

1. A method for performing a built-in self-test (BIST) of a voltage monitor circuit, the method comprising:
configuring the voltage monitor circuit into a test mode, comprising:
decoupling a functional mode monitoring path by opening a first switch,
establishing a test path by closing a second switch, and
enabling an analog buffer to generate test voltages,
applying a high threshold voltage to a non-inverting input of a comparator in the voltage monitor circuit;
applying a low threshold voltage to the non-inverting input of the comparator; and
monitoring an output of the comparator in response to the applied threshold voltages to verify operation of the comparator and bandgap sources in the voltage monitor circuit,
wherein an inverting input of the comparator is coupled to a monitor reference voltage from a monitor bandgap source, and
wherein the high threshold voltage and the low threshold voltage are derived from a separate regulator bandgap source to provide redundant monitoring.

2. The method of claim 1, further comprising, after verifying operation condition of the comparator and bandgap sources:
configuring the voltage monitor circuit into a functional operating mode, comprising:
establishing the functional mode monitoring path by closing the first switch,
decoupling the test path by opening the second switch, and
disabling the analog buffer; and
monitoring a voltage difference at the inputs of the comparator during the functional operating mode.

3. The method of claim 1, further comprising, after monitoring the output of the comparator:
testing operation of the first switch and the second switch, comprising:
disabling the analog buffer,
charging a parasitic capacitance at the non-inverting input of the comparator,
opening the second switch to decouple the test path, and
closing the first switch to establish the functional mode monitoring path; and
monitoring the output of the comparator during switching transitions to verify operation condition of the first switch and the second switch.

4. The method of claim 1, wherein the high threshold voltage equals a reference voltage from the regulator bandgap source plus a delta voltage, and the low threshold voltage equals the reference voltage minus the delta voltage.

5. The method of claim 4, wherein the delta voltage is trimmable.

6. The method of claim 1, wherein the voltage monitor circuit is one of a plurality of voltage monitor circuits in a system-on-chip, and wherein the method further comprises sequentially testing each voltage monitor circuit.

7. The method of claim 1, further comprising:
storing fault conditions detected during the BIST in registers; and
initiating protective actions in response to detecting voltage excursions outside acceptable limits.

8. A method for testing and operating a voltage monitor circuit in an electronic system, the method comprising:
performing a built-in self-test (BIST) of the voltage monitor circuit, comprising:
testing bandgap sources and a comparator of the voltage monitor circuit by applying test voltages to an input of the comparator and monitoring output transitions of the comparator, and
testing switches in the voltage monitor circuit by manipulating the switches and monitoring resulting output changes of the comparator; and
transitioning to a functional operating mode after performing the BIST and verifying a functional mode operation of the voltage monitor circuit, comprising:
establishing a monitoring path from a regulated voltage to the comparator,
decoupling a test path from the comparator, and
monitoring output of the comparator to detect voltage excursions outside acceptable limits,
wherein the voltage monitor circuit includes separate regulator and monitor bandgap sources to provide redundant monitoring.

9. The method of claim 8, wherein testing the bandgap sources and the comparator comprises:
configuring the voltage monitor circuit into a test mode by decoupling the monitoring path, establishing the test path, and enabling an analog buffer;
applying a high threshold voltage to a non-inverting input of the comparator;
applying a low threshold voltage to the non-inverting input of the comparator; and
monitoring the output of the comparator in response to the applied threshold voltages.

10. The method of claim 8, wherein testing the switches comprises:
configuring the voltage monitor circuit into a switch test mode;
charging a parasitic capacitance at a non-inverting input of the comparator;
manipulating states of the switches to transition between the test path and the monitoring path; and
monitoring the output of the comparator during the transitions to verify operation of the switches.

11. The method of claim 8, wherein establishing the monitoring path comprises closing a first switch that couples the regulated voltage to a non-inverting input of the comparator.

12. The method of claim 8, wherein decoupling the test path comprises opening a second switch that couples an analog buffer to a non-inverting input of the comparator.

13. The method of claim 8, wherein the voltage monitor circuit is one of a plurality of voltage monitor circuits in a system-on-chip, and wherein the method further comprises sequentially testing each voltage monitor circuit.

14. The method of claim 8, further comprising, in response to detecting voltage excursions outside acceptable limits, triggering protective actions including signaling a fault condition, storing the fault condition in a register, triggering a system reset, cutting off a supply voltage, or a combination thereof.

15. A voltage monitor circuit for providing continuous voltage monitoring with built-in self-test capability, the voltage monitor circuit comprising:
a regulator bandgap source configured to provide a reference voltage;
a regulator coupled to the regulator bandgap source and configured to generate a regulated voltage;
a monitor bandgap source configured to provide a monitor reference voltage independent from the reference voltage;
a comparator having a non-inverting input and an inverting input, wherein the inverting input is coupled to the monitor reference voltage;
a first switch coupled between the regulator and the non-inverting input of the comparator and configured to establish a functional mode monitoring path during normal operation;
an analog buffer coupled to the regulator bandgap source and configured to generate a high threshold voltage and a low threshold voltage for testing;
a multiplexer coupled to the analog buffer and configured to select between the high threshold voltage and the low threshold voltage based on a control signal; and
a second switch coupled between the multiplexer and the non-inverting input of the comparator and configured to establish a test path during built-in self-test operations.

16. The voltage monitor circuit of claim 15, wherein the first switch is configured to be in a closed position and the second switch is configured to be in an open position during a functional operating mode of the voltage monitor circuit.

17. The voltage monitor circuit of claim 15, wherein the first switch is configured to be in an open position and the second switch is configured to be in a closed position during a built-in self-test (BIST) operating mode of the voltage monitor circuit.

18. The voltage monitor circuit of claim 15,
wherein the high threshold voltage equals the reference voltage plus a delta voltage, and
wherein the low threshold voltage equals the reference voltage minus the delta voltage.

19. The voltage monitor circuit of claim 15, further comprising a parasitic capacitance at the non-inverting input of the comparator, wherein the parasitic capacitance is configured to charge and discharge during a switch testing mode to verify operation condition of the first switch and the second switch.

20. The voltage monitor circuit of claim 15, wherein the analog buffer comprises:
a buffer amplifier having a non-inverting input coupled to the reference voltage;
a p-channel transistor having a gate terminal coupled to an output of the buffer amplifier, a source terminal coupled to a supply voltage, and a drain terminal;
a first resistor having a first terminal coupled to the drain terminal of the p-channel transistor and a second terminal coupled to a first node;
a second resistor having a first terminal coupled to the first node and a second terminal coupled to a second node; and
a third resistor having a first terminal coupled to the second node and a second terminal coupled to ground,
wherein the first node provides the high threshold voltage and the second node provides the low threshold voltage.
